(19) United States
(12) Patent Application Publication
(10) Pub. No.: US 2024/0213001 A1
(43) Pub. Date: Jun. 27, 2024

(54) SUBSTRATE TREATMENT METHOD AND SUBSTRATE TREATMENT APPARATUS

(71) Applicant: SEMES CO., LTD., Cheonan-si (KR)

(72) Inventors: Young Jo JIN, Hwaseong-si (KR); Sang Jeong LEE, Hwaseong-si (KR); Min Sung JEON, Osan-si (KR); Tae Hwan LEE, Cheonan-si (KR); Min Hee HONG, Suwon-si (KR)

(73) Assignee: SEMES CO., LTD., Cheonan-si (KR)

(21) Appl. No.: 18/542,776

(22) Filed: Dec. 18, 2023

(30) Foreign Application Priority Data
Dec. 21, 2022 (KR) 10-2022-0180834

(51) Int. Cl. H01J 37/32; H01L 21/3065; H01L 21/687

(52) U.S. Cl. CPC H01J 37/32724; H01J 37/32522; H01L 21/30655; H01L 21/68742; H01J 2237/3341

(57) ABSTRACT

Proposed are a substrate treatment method and a substrate treatment apparatus that are capable of adjusting cooling efficiency for a substrate. According to an embodiment of the present disclosure, there may be provided the substrate treatment method including a heating process in which a surface of the substrate is heated and a cooling process in which the substrate is cooled by supplying a cooling gas to a lower surface of the substrate. Furthermore, the cooling process includes a cooling condition controlling process in which a cooling condition is controlled.

### CROSS REFERENCE TO RELATED APPLICATION

The present application claims priority to Korean Patent Application No. 10-2022-0180834, filed on Dec. 21, 2022, the entire contents of which are incorporated by reference herein for all purposes.

### BACKGROUND OF THE INVENTION

### 1. Field of the Invention

The present disclosure relates to a substrate treatment method and a substrate treatment apparatus.

### 2. Description of the Related Art

In order to manufacture a semiconductor device, a desired pattern is formed on a substrate by performing various processes such as a photolithography process, an etching process, an ashing process, an ion implantation process, a thin film deposition process, a cleaning process, and so on. Among the various processes, the etching process is a process of removing a selected heating region in a film formed on the substrate, and a wet etching process and a dry etching process are used.

For the dry etching process, an etching apparatus using plasma is used. Generally, in order to form the plasma, an electromagnetic field is generated in an inner space of a chamber, and the electromagnetic field excites a process gas provided in the chamber into a plasma state.

Plasma refers to an ionized gaseous state composed of ions or electrons, radicals, and so on. Plasma may be generated by a very high temperature, a strong electric field, or an RF electromagnetic field. In a semiconductor device manufacturing process, the etching process may be performed using plasma.

In some plasma processes, a Rapid Thermal Process (RTP) apparatus in which a heat source is disposed is used on an upper portion of the substrate so as to thermally treat the substrate. An upper heat source may heat the substrate at a faster speed than a lower heat source. Generally, a thermal process apparatus that uses the upper heat source maintains a temperature of the substrate by cooling the substrate in an air cooling method. Although the air cooling method has an advantage of cooling the substrate with a simple structure. However, since a cooling speed is slow and cooling efficiency is low, there is a difficulty in maintaining a temperature of the substrate constant in response to a rapid increase in the substrate temperature. For example, in an Atomic Layer Deposition (ALD) process in which heating and cooling of the substrate is repeated, or an Atomic Layer Etching (ALE) process, a cooling speed in the cooling of the substrate using the air cooling method is substantially slow compared to a heating speed of the substrate, so that the temperature of the substrate and the temperature of the treatment space may increase as the process is repeated. Accordingly, the same process conditions may not be maintained consistently, so that the process recipe may become unstable. In addition, there is a possibility that a thin film or a pattern on the substrate may be damaged as the substrate is overheated due to an increase in temperature of the substrate. In addition, overheating of the substrate may change the physical properties of the thin film or may cause an overetching of the thin film.

Meanwhile, a water cooling method, which is another method used to cool the substrate, has a higher cooling efficiency than the cooling efficiency of the air cooling method, but the substrate is capable of being cooled only when the substrate is seated on a support member (for example: a cooling plate). In addition, since a cooling member for cooling the substrate is provided inside the support member in the form of a cooling flow path and a configuration in which cooling heat is indirectly transferred to the substrate is provided, heat transfer efficiency may be reduced in some environments (for example: a vacuum environment). In addition, since a cooling temperature may be limited according to a use temperature range of cooling fluid provided to the cooling member, it is difficult to rapidly cool the substrate.

### SUMMARY OF THE INVENTION

Accordingly, the present disclosure has been made keeping in mind the above problems occurring in the related art, and an objective of the present disclosure is to provide a substrate treatment method and a substrate treatment apparatus that are capable of rapidly cooling a substrate, thereby being capable of maintaining a temperature of the substrate in a predetermined temperature range during an overall treatment processes.

In addition, another objective of the present disclosure is to provide a substrate treatment method and a substrate treatment apparatus that are capable of adjusting cooling efficiency of a substrate.

The problems to be solved by the inventive concept are not limited to the above-mentioned problems, and the problems not mentioned will be clearly understood by those of ordinary skill in the art to which the inventive concept belongs from the present specification and the accompanying drawings.

According to an embodiment of the present disclosure, there is provided a substrate treatment method including: a heating process in which a surface of a substrate is heated; and a cooling process in which the substrate is cooled by supplying a cooling gas to a lower surface of the substrate.

According to an embodiment of the present disclosure, there is provided a substrate treatment apparatus including: a chamber having a treatment space therein; a support member which is disposed in an internal space of the treatment space and on which a substrate to be treated is seated, the support member being provided with a plurality of gas discharge holes; a lift pin configured to lift the substrate from the support member; a cooling unit configured to cool the substrate by discharging a cooling gas through the gas discharge holes; a heating unit configured to heat the substrate by supplying thermal energy to the treatment space; and a controller configured to control the lift pin, the cooling unit, and the heating unit.

According to an embodiment of the present disclosure, there is provided a substrate treatment method of etching a surface of a substrate at an atomic layer level. The substrate treatment method includes: a surface treatment process in which the surface of the substrate is modified by using plasma; and a thermal treatment process for generating a desorption reaction on the surface of the substrate that is surface-treated in the surface treatment process, wherein the surface treatment process and the thermal treatment process may constitute one cycle and may be repeated one or more times. The thermal treatment process may include: a heating process in which the surface of the substrate is heated; and a cooling process in which the substrate is cooled by supplying a cooling gas to a lower surface of the substrate.

According to an embodiment of the present disclosure, by using a direct cooling method, a cooling speed and cooling efficiency may be increased, so that a temperature increase phenomenon of the entire substrate and the treatment space due to the repeated processes may be prevented. Accordingly, since the temperature of the entire substrate and the treatment space may be maintained in a predetermined range, the substrate may be treated under the same process condition even in the repeated processes. That is, process stability and process reproducibility may be secured. In addition, since overheating of the substrate is prevented, deformation of the substrate and damage to the substrate (for example: damage to a pattern, damage to a surface of a thin film, and so on) due to overheating of the substrate may be prevented.

Particularly, since the substrate is cooled in a non-contact manner by using the cooling gas while the substrate is moved upward from the support member, the cooling efficiency of the substrate may be controlled by adjusting the condition of the cooling gas and the height of the substrate.

In addition, the process time may be reduced by rapid heating and rapid cooling. Furthermore, since the cooling treatment is capable of being performed regardless of a change in the height of the substrate, intensive thermal treatment may be performed on the surface of the substrate by cooling the lower surface of the substrate while the heating process is performed.

The effects of the inventive concept are not limited to the above-mentioned effects, and the other unmentioned effects will become apparent to those skilled in the art from the following description and drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view illustrating an example of a substrate treatment system to which the present disclosure is applied;

FIG. 2 and FIG. 3 are cross-sectional views schematically illustrating a process unit illustrated in FIG. 1;

FIG. 4 is an enlarged perspective view illustrating a support member according to an embodiment of the present disclosure; and

FIG. 5 is a flowchart illustrating a substrate treatment method according to an embodiment of the present disclosure.

### DETAILED DESCRIPTION OF THE INVENTION

Hereinafter, exemplary embodiments of the present disclosure will be described in detail with reference to the accompanying drawings so that those skilled in the art can easily implement the present disclosure. The present disclosure is not limited to the exemplary embodiments described herein and may be embodied in many different forms.

In order to clearly describe the present disclosure, parts irrelevant to the description are omitted, and the same reference numerals designate the same or similar components throughout the specification.

In addition, in various exemplary embodiments, components having the same configuration will be described only in representative exemplary embodiments by using the same reference numerals, and in other exemplary embodiments, only configurations different from the representative exemplary embodiments will be described.

Throughout the specification, when a part is said to be “connected (or coupled)” to another part, an expression such as “connected (or coupled)” is intended to include not only “directly connected (or coupled)” but also “indirectly connected (or coupled)” having a different member interposed therebetween. In addition, it will be further understood that when a part “comprises”, “includes”, or “has” an element, this means that other elements are not excluded but may be further included, unless otherwise stated.

Unless defined otherwise, all terms used herein including technical or scientific terms have the same meanings as generally understood by a person having ordinary knowledge in the art to which the present disclosure pertains. The terms defined in general dictionaries are construed as having meanings consistent with the contextual meanings of the art, but not interpreted as ideal meanings or excessively formal meanings unless explicitly defined in the present application.

A substrate according to an embodiment of the present disclosure may be a silicon substrate based on a semiconductor wafer. At this time, the substrate may include a thin film formed on an upper portion of the substrate.

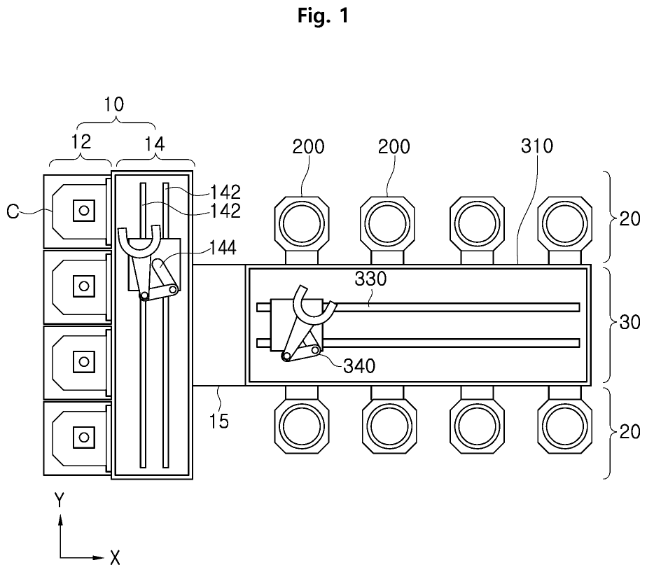

FIG. 1 is a plan view illustrating an example of a substrate treatment system to which the present disclosure is applied.

Referring to FIG. 1, a substrate treatment system to which the present disclosure is applied may include an index module 10, a treatment module 20, and a substrate transfer module 30 configured to transfer a substrate between the index module 10 and the treatment module 20. According to an embodiment of the present disclosure, the index module 10 and the treatment module 20 may be sequentially arranged in a row.

The index module 10 may include a load port 12 where a carrier C in which the substrate is stored is seated, and may include an index frame 14 configured to pull out a substrate W from the carrier C seated in the load port 12 or to bring a substrate in which a process treatment is finished into the carrier C. The load port 12 is positioned on an opposite side of the treatment module 20 with respect to the index frame 14. The carrier C is disposed on the load port 12 and may be provided with a plurality of carriers C, and the substrates W may be stored in the carriers C.

An index robot 144 may be provided inside the index frame 14. The index robot 144 may be provided such that the index robot 144 is capable of being moved along a rail 142. The index robot 144 may receive the substrate from the carrier C, and may transfer the substrate to a load lock chamber 15 in which the substrate is temporarily stored or may transfer the substrate temporarily stored in the load lock chamber 15 to an inside of the carrier C.

The treatment module 20 may include at least one process unit 200 in which a process treatment of the substrate is performed. As illustrated in FIG. 1, the process unit 200 may be provided with a plurality of process units 200. Each of the process units 200 may perform the same process, or may perform different processes.

The substrate transfer module 30 may be disposed adjacent to the treatment module 20, and may receive the substrate from the load lock chamber 15 and then may transfer the substrate to the treatment module 20, or may transfer the substrate in which the process treatment is finished in the treatment module 20 to the load lock chamber 15. The substrate transfer module 30 may include a rail 330 disposed along the direction in which the process units 200 are disposed, and may include a substrate transfer robot 340 configured to move along the rail 330 and to transfer the substrate. The substrate transfer robot 340 may return the substrate while moving in an inner space of a return chamber 310.

Meanwhile, as illustrated in FIG. 1, the treatment module 20 may be provided in an in-line type, but may be provided in a cluster type unlike the in-line type illustrated in FIG. 1.

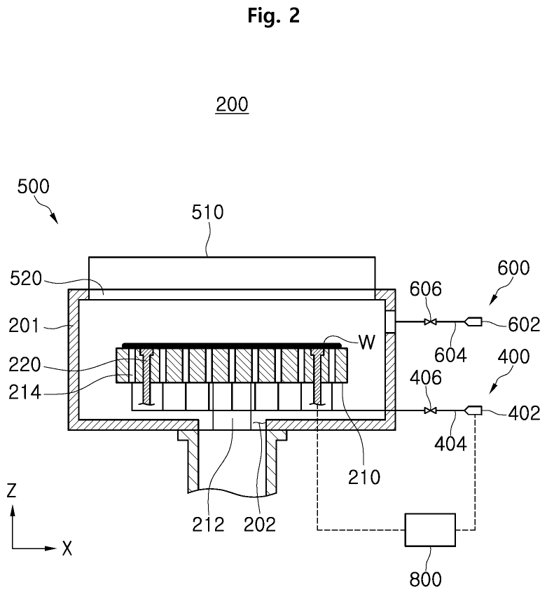

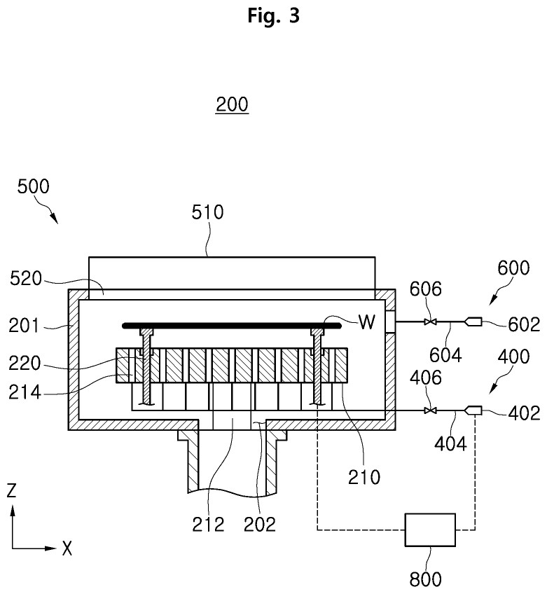

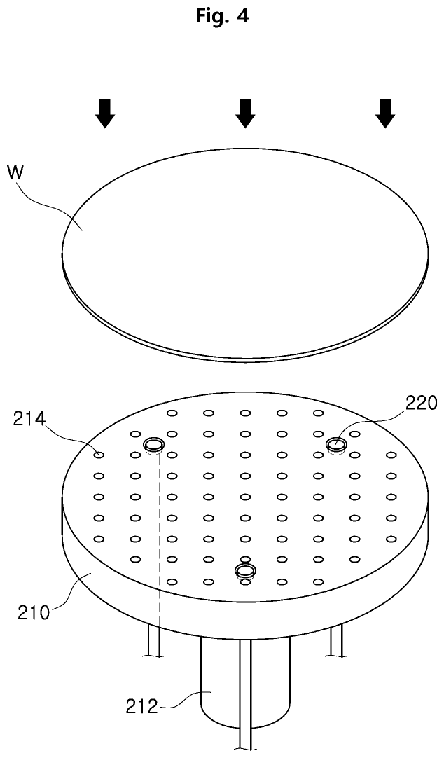

FIG. 2 and FIG. 3 are cross-sectional views schematically illustrating a process unit illustrated in FIG. 1, and FIG. 4 is an enlarged perspective view illustrating a support member according to an embodiment of the present disclosure.

The process unit 200 according to an embodiment of the present disclosure includes a substrate treatment apparatus for processing a substrate. The substrate treatment apparatus according to the present disclosure may be used in a process in which a substrate thermal treatment process is included. As an example, the substrate treatment apparatus according to the present disclosure may be used in a thermal Atomic Layer Deposition (t-ALD) process, a thermal Atomic Layer Etching (t-ALE) process, and so on in which a surface of the substrate is treated at an atomic layer level by using heat.

Referring to FIG. 2 and FIG. 3, the substrate treatment apparatus may include a chamber 201, a support member 210, a lift pin 220, a cooling unit 400, a heating unit 500, a gas supply unit 600, and a controller 800.

The chamber 201 has an inner portion provided with a process space in which the substrate W is placed and a plasma process is performed. Such a chamber may have an opening part (not illustrated) formed on a side wall of the chamber. The substrate may enter and exit inner and outer portions of the chamber through the opening part (not illustrated). The opening part (not illustrated) may be opened and closed by an opening and closing member such as a door. An exhaust hole 202 may be formed in a bottom surface of the chamber 201. The exhaust hole 202 may provide a passage through which gas and reaction by-products that remain in a thermal treatment space inside the chamber 201 are discharged to the outside.

The support member 210 on which the substrate W is seated is disposed inside a treatment space of the chamber 201, and the support member 210 may be provided in a circular plate shape. The support member 210 may be supported by a support shaft 212, and the substrate W to be treated may be seated on an upper surface of the support member 210.

The support member 210 includes a plurality of gas discharge holes 214. The plurality of gas discharge holes 214 penetrates the support member in up and down directions, and is connected to the cooling unit 400. A cooling gas supplied from the cooling unit 400 may be discharged toward a lower surface of the substrate W through the plurality of gas discharge holes 214. The cooling gas discharged to the lower surface of the substrate W cools the substrate W, thereby being capable of maintaining a temperature of the substrate W to be in a predetermined range. The cooling gas is discharged from the gas discharge hole 214 and reaches the lower surface of the substrate W, thereby directly transferring cooling heat to the substrate W.

The lift pin 220 may be provided with a plurality of lift pins 220, may support the lower surface of the substrate W, and may be accommodated in a plurality of pin holes that penetrates the support member 210 in the up and down directions. The lift pin 220 may be lifted upward while being in a state in which the lift pin 220 is in contact with the lower surface of the substrate W and supports the substrate W. For example, as illustrated in FIG. 4, three lift pins 220 supporting different regions of the substrate W are provided, so that the substrate W may be moved upward or downward from the support member 210 according to a process. Lift driving of each lift pin 220 may be individually or integrally performed, and the lift driving of the lift pin 220 may be performed by a driving apparatus such as a linear motor, a cylinder, a ball screw, and so on. The number of the lift pin 220 may be increased or decreased as needed, and a placement position of the lift pin 220 may be changed as needed. When a cooling process for the substrate W is performed, the lift pin 220 maintains the substrate W to be in a state in which the substrate W is spaced apart from the upper surface of the support member 210. The lift driving of the lift pin 220 may be controlled by the controller 800.

As illustrated in FIG. 3, the cooling unit 400 may cool the substrate W in a non-contact manner by supplying cooling gas to the lower surface of the substrate W while the substrate W is moved upward from the upper surface of the support member 210. The cooling unit 400 may supply the cooling gas through the gas discharge hole 214 by using a cooling gas supply means, the gas discharge hole 214 being formed in the support member 210.

The cooling gas supply means may include a cooling gas supply source 402, a cooling gas supply line 404, and a valve 406 mounted on the cooling gas supply line 404.

The cooling gas supply source 402 supplies the cooling gas to the plurality of gas discharge holes 214 through the cooling gas supply line 404, and the amount of cooling gas supplied to the cooling gas supply line 404 may be adjusted by the valve 406. For example, the cooling gas may be nitrogen gas. A temperature and a supply amount of the cooling gas supplied to the cooling gas supply line 404 may be controlled by the controller 800.

A conventional support member includes a cooling flow path formed inside the conventional support member so as to cool the substrate W, and includes a gas supply hole for maximizing cooling efficiency between the cooling flow path and the substrate W. On the other hand, in the support member 210 according to the present disclosure, functions of the cooling flow path and the gas supply hole may be performed by the gas discharge hole 214. That is, since the functions that was performed by the two components are capable of being performed by one component, an internal structure of the support member 210 may be simplified. In addition, cooling of the substrate W, which was only possible to be performed in a state in which the substrate W is seated on the support member, is possible to be performed even in a state in which the substrate W is spaced apart from the support member, and indirect cooling performed by the cooling flow path is changed to direct cooling by the cooling gas, so that the cooling speed and the cooling efficiency may be significantly increased.

The heating unit 500 may be provided with an upper heat source 510 for generating thermal energy, and may supply heat to the treatment space. The substrate W may be heated by the thermal energy supplied to the treatment space. According to an embodiment of the present disclosure, the upper heat source 510 may be a microwave generator, and may be transmitted to the treatment space through a waveguide (not illustrated). As illustrated in FIG. 3, while a process of heating the substrate W is performed by the upper heat source 510, the substrate W may be maintained in a state in which the substrate W is spaced apart from the upper surface of the support member 210.

A window 520 may be formed between the upper heat source 510 and the support member 210. The window 520 may perform a function of protecting etching by-products generated as the process progresses from being deposited on the upper heat source 510. As an example, the window 520 may be a dielectric window. The window 520 is formed of a transparent member, so that a wavelength generated from the upper heat source 510 is capable of being transmitted through the window 520. The wavelength transmitted through the window 520 to the treatment space may supply heat to the substrate W.

The heating unit 500 of the present disclosure configured as described above is an apparatus for Rapid Thermal Processing (RTP), and may be used when a rapid rise of temperature is required in a short time. In addition, the upper heat source 510 is not limited to the microwave generator, and may include other thermal treatment means capable of performing the RTP. For example, the upper heat source 510 may include one of the microwave generator, a laser generator, and an infrared lamp. On the other hand, the upper heat source 510 may be positioned above and to a side of the support member 210 instead of directly above the support member 210.

The cooling unit 400 may cool the substrate W in which the process has been completed to room temperature or to a temperature required for the next process. In addition, the cooling unit 400 may cool the substrate W while the thermal treatment of the substrate W is performed, thereby preventing the substrate W from overheating. Particularly, due to a lower portion of the substrate W being cooled by the cooling unit 400 during the RTP, the thermal energy applied to an upper surface of the substrate W is minimized to reach the lower surface of the substrate W, so that the thermal treatment may be concentrated on the upper surface (the surface) of the substrate W. By rapidly cooling the substrate W, the cooling unit 400 may prevent overheating of the substrate W, thereby being capable of preventing deformation and damage (including damage to the lower portion of the substrate W) of the substrate W caused by overheating of the substrate W and being capable of preventing changes in physical properties of the thin film and so on.

The gas supply unit 600 may supply the gas required for the process to the chamber 201. Specifically, the gas supply unit 600 may supply a process gas including oxygen, a precursor, or a purge gas to the treatment space. The gas supply unit 600 may include a gas supply source 602, a gas supply line 604, and a gas injection nozzle. The gas supply line 604 may connect the gas supply source 602 and the gas injection nozzle to each other. A gas supply valve 606 configured to open or close a passage of the gas supply line 604 or configured to adjust a flow rate of fluid flowing along the passage may be mounted on the gas supply line 604.

Although only one gas supply source 602 and one gas supply valve 606 are illustrated in the drawings, the gas supply source 602 may include a plurality of gas supply sources and a plurality of gas supply valves capable of independently controlling the supply of each gas. At this time, the plurality of gases may include a process gas used in a substrate treatment process, a precursor, an inert gas for purging, and so on.

The controller 800 may control the lift pin 220, the cooling unit 400, and the heating unit 500. In addition, the controller 800 may control the gas supply unit 600.

The controller 800 may control the lift pin 220 so that the cooling treatment of the substrate W performed by the cooling unit 400 is performed in a state in which the substrate W is spaced apart from the upper surface of the support member 210. In addition, the controller 800 may control the lift pin 220 so that the substrate thermal treatment performed by the heating unit 500 is performed in a state in which the substrate W is spaced apart from the upper surface of the support member 210. The controller 800 may control a lifting height of the lift pin 220 by controlling the driving apparatus of the lift pin 220.

The controller 800 may adjust the cooling efficiency by controlling the cooling unit 400. Specifically, the controller 800 may control a discharge amount and a temperature of the cooling gas supplied to the lower surface of the substrate W by controlling the cooling gas supply means. The controller 800 may control the cooling efficiency of the substrate W by controlling the discharge amount and the temperature of the cooling gas. As an example, the controller 800 may increase the cooling efficiency of the substrate W by increasing the discharge amount of the cooling gas. As an example, the controller 800 may increase the cooling efficiency of the substrate W by lowering the temperature of the cooling gas.

In addition, the controller 800 may control the cooling efficiency by controlling the lifting height of the lift pin 220. When the process of cooling the substrate W is performed by the cooling unit 400, the controller 800 may adjust a separation distance between the substrate W and the upper surface of the support member 210 by controlling the lifting height of the lift pin 220. By adjusting the separation distance between the substrate W and the upper surface of the support member 210, the cooling efficiency of the substrate W may be controlled. The process of cooling the substrate W performed by the cooling unit 400 is performed in a state in which the substrate W is moved upward from the upper surface of the support member 210. At this time, the controller 800 may increase the cooling efficiency by narrowing the separation distance between the substrate W and the upper surface of the support member 210.

In addition, the controller 800 may control the heating efficiency by controlling the lifting height of the lift pin 220. When the process of heating the substrate W is performed by the heating unit 500, the controller 800 may adjust a separation distance between the substrate W and the upper heat source 510 by controlling the lifting height of the lift pin 220. By adjusting the separation distance between the substrate W and the upper heat source 510, the heating efficiency of the substrate W may be controlled. The process of heating the substrate W performed by the heating unit 500 is performed in a state in which the substrate W is moved upward from the upper surface of the support member 210. At this time, the controller 800 may increase the heating speed by narrowing the separation distance between the substrate W and the upper heat source 510. Particularly, when the microwave generator is provided as the upper heat source 510, the controller 800 may control a movement path of a microwave by controlling the height of the substrate W, thereby being capable of adjusting the heating efficiency.

The controller 800 may determine the lifting height of the lift pin 220. That is, the controller 800 may determine the lifting height of the lift pin 220 corresponding to a process temperature by using map data indicating the change in the substrate temperature according to the lifting height of the substrate W. The map data may be data in which the lifting height of the lift pin 220 that corresponds to a target temperature change amount of the substrate W is stored. The map data indicating the change in the substrate temperature according to the lifting height of the substrate W may be learned and updated through simulation or experimental data.

Meanwhile, the controller 800 may adjust the heating efficiency by controlling the heating unit 500. Specifically, the controller 800 may control the heating efficiency by adjusting the intensity of the thermal energy supplied from the upper heat source 510 to the treatment space.

In addition, the controller 800 may control the type of gas supplied to the processing space, the flow rate of gas, and so on by controlling the gas supply unit 600 according to the process.

Although not illustrated in detail, the process unit 200 may further include a plasma generation unit in the treatment space. The plasma generation unit (not illustrated) may generate plasma in the treatment space inside the chamber 201. The plasma generated by the plasma generation unit (not illustrated) may be formed in an upper region of the support member 210. The plasma generation unit (not illustrated) may excite the process gas in a plasma state, the process gas being supplied to the treatment space by the gas supply unit 600. As an example, the plasma generation unit (not illustrated) may be provided in a form in which one of an Inductively Coupled Plasma (ICP) source, a Capacitively Coupled Plasma (CCP) source, or a microwave source is used. As illustrated in FIG. 2, the plasma generation unit (not illustrated) may generate plasma in the treatment space while the substrate W is in a state in which the substrate W is seated on the support member 210.

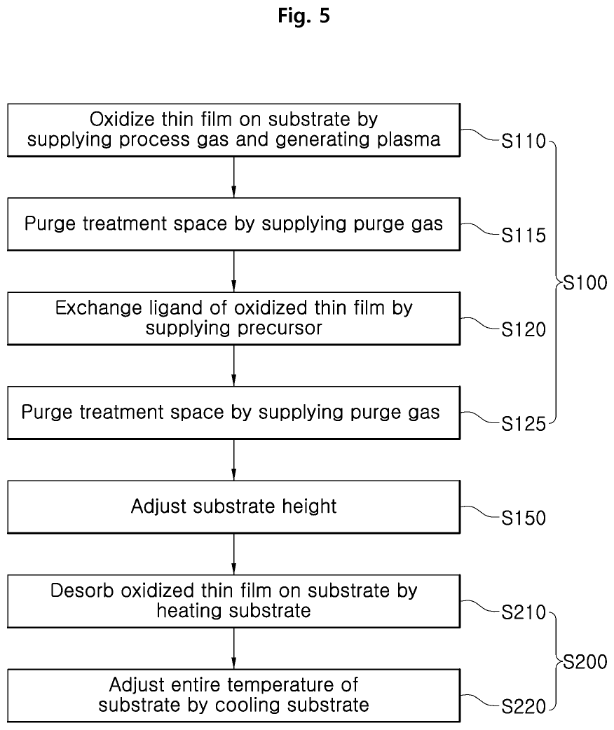

FIG. 5 is a flowchart illustrating a substrate treatment method according to an embodiment of the present disclosure. A substrate treatment method according to an embodiment of the present disclosure may be performed by the substrate treatment apparatus of the present disclosure. Hereinafter, the substrate treatment method according to an embodiment of the present disclosure will be described with reference to FIG. 1 to FIG. 5.

Referring to FIG. 5, the substrate treatment method according to an embodiment of the present disclosure includes an atomic layer etching method. The substrate treatment method according to an embodiment of the present disclosure includes a surface treatment process S100 and a thermal treatment process S200. The surface treatment process S100 and the thermal treatment process S200 are performed as one cycle, and a desired etching thickness may be obtained by repeating the cycle one or more times.

The surface treatment process S100 is a process for modifying a surface of a substrate. The surface treatment process S100 may include an oxidation process S110 and a modification process S120. As illustrated in FIG. 2, the surface treatment process S100 may be performed in a state in which the substrate W is seated on the support member 210.

The oxidation process S110 is a process of oxidizing the surface of the substrate, and may be performed by a plasma treatment on the substrate W. The oxidation process S110 includes a process in which a process gas is supplied to the treatment space where the substrate W exists and then the process gas is converted into plasma. At this time, the process gas may include oxygen. The process gas radicalized and ionized by the plasma generation unit (not illustrated) may generate an oxide layer (an oxide film) by reacting with the thin film on the substrate W. At this time, a thickness of the generated oxide layer may be determined according to an oxidation condition.

The modification process S120 is a process of exchanging a ligand of the surface of the substrate, and includes a process of supplying a precursor to the treatment space by using the gas supply unit 600. The precursor supplied to the treatment space is physically adsorbed to the oxide film generated in the oxidation process S110. After then, the oxide film formed on the substrate W is not etched, but bond energy of the oxide film may be weakened through a ligand exchange reaction.

The cycle according to an embodiment of the present disclosure may further include a purge process. The purge process is a process in which a residual gas and process by-products in the treatment space are removed by supplying the purge gas to the treatment space. The purge process may be included in the surface treatment process S100.

A purge process S115 may be performed between the oxidation process S110 and the modification process S120. The purge process S115 is a process in which the purge gas is supplied to the treatment space where the oxidation process S110 is completed, and may be performed by the gas supply unit 600 of the process unit 200. The purge gas may be supplied after the gas supply process in the oxidation process S110 is stopped. The purge gas supplied to the treatment space may be discharged outside the chamber 201 through the exhaust hole 202. According to the purge process S115, the residual gas and the reaction by-products which are supplied in the oxidation process S110 and which are remaining in the treatment space may be removed. As an example, an inert gas such as argon (Ar), helium (He), and so on may be used as the purge gas.

When the modification process S120 is completed, another purge process S125 may be performed. The purge process S125 is a process in which the purge gas is supplied to the treatment space where the modification process S120 is completed, and may be performed by the gas supply unit 600 of the process unit 200. The purge gas may be supplied after the gas supply process in the modification process S120 is stopped. The purge gas supplied to the treatment space may be discharged outside the chamber 201 through the exhaust hole 202. According to the purge process S125, the precursor and the reaction by-products which are supplied in the modification process S120 and which are remaining in the treatment space may be removed. As an example, an inert gas such as argon (Ar), helium (He), and so on may be used as the purge gas.

When the surface treatment process S100 is completed, the thermal treatment process S200 is performed. In the thermal treatment process S200, a desorption reaction occurs on the surface of the surface-treated substrate.

The thermal treatment process S200 may include a heating process S210 and a cooling process S220. As illustrated in FIG. 3, the thermal treatment process S200 may be performed in a state in which the substrate W is moved upward from the upper surface of the support member 210. Therefore, between the surface treatment process S100 and the thermal treatment process S200, a substrate height adjustment process S150 in which a height of the substrate W with respect to the support member 210 is adjusted may be performed.

In the heating process S210, the surface of the substrate W may be heated. The heating process S210 includes a process of supplying thermal energy to the treatment space where the substrate W in which the surface treatment process is performed exists. The substrate W may be heated in a non-contact manner by the thermal energy supplied to the treatment space. The process of supplying the thermal energy to the treatment space may be performed simultaneously with the process of supplying the inert gas to the treatment space. In the heating process S210, heat is supplied to the substrate W by using the heating unit 500 that includes the upper heat source 510 and, at the same time, the inert gas is supplied by using the gas supply unit 600, so that the oxide film in which the bond energy is weakened may be desorbed at an atomic layer level. The upper heat source 510 may be one of the microwave generator, the laser generator, and the infrared lamp, and argon (Ar), helium (He), and so on may be used as the inert gas. According to an embodiment of the present disclosure, a microwave may be applied to the treatment space by using the microwave generator. The oxide film desorbed by the heating process S210 may be discharged to the exhaust hole 202 along with the inert gas supplied to the thermal treatment space.

The heating process S210 may further include a process of controlling the heating speed and the heating efficiency by adjusting the distance between the substrate W and the upper heat source 510. The distance between the substrate W and the upper heat source 510 may be adjusted by adjusting the height of the lift pin 220 by the controller 800.

In the cooling process S220, the substrate W may be cooled by supplying the cooling gas to the lower surface of the substrate W. The cooling process S220 is performed so as to maintain a temperature of the substrate W at a set temperature range. The cooling gas may be supplied to the lower surface of the substrate W only while the cooling process S220 is performed. When the cooling process S220 is not performed, the supply of the cooling gas may be stopped. The cooling process S220 includes a process of controlling the cooling efficiency of the substrate W by controlling the cooling condition.

The cooling process S220 is performed immediately after the heating process S210 is performed, so that the substrate heated in the heating process S210 may be cooled. Particularly, as the cooling process S220 is performed by the cooling gas that directly transfers cooling heat to the lower surface of the substrate W, the cooling speed and the cooling efficiency of the substrate W may be significantly increased compared to the conventional cooling process. In addition, the cooling condition may be controlled through the cooling gas control, and a cooling temperature range of the direct cooling method is wider than a cooling temperature range of an indirect cooling method.

In the cooling process S220, the controller 800 may control the cooling efficiency of the substrate W by controlling the cooling condition. At this time, the cooling condition may include the discharge amount of the cooling gas, the temperature of the cooling gas, and the separation distance between the substrate W and the upper surface of the support member 210.

In the cooling process S220, the controller 800 may adjust the cooling efficiency by controlling the cooling unit 400. Specifically, the controller 800 may control a discharge amount and a temperature of the cooling gas supplied to the lower surface of the substrate W by controlling the cooling gas supply means. The controller 800 may control the cooling efficiency of the substrate W by controlling the discharge amount and the temperature of the cooling gas. As an example, the controller 800 may increase the cooling efficiency of the substrate W by increasing the discharge amount of the cooling gas. As an example, the controller 800 may increase the cooling efficiency of the substrate W by lowering the temperature of the cooling gas. In addition, the controller 800 may control the cooling efficiency of the substrate W by adjusting the separation distance between the substrate W and the upper surface of the support member 210. As an example, the controller 800 may increase the cooling efficiency by narrowing the separation distance between the substrate W and the upper surface of the support member 210.

Optionally, the cooling process S220 is performed simultaneously with the heating process S210, so that the substrate W may be prevented from overheating during the heating process S210. The cooling process S220 that is performed simultaneously with the heating process S210 may prevent the substrate W from being overheated by the rapid thermal treatment of the heating process S210, and may be performed until the heating process S210 is finished, thereby being capable of cooling the substrate W in which the temperature thereof is increased. Particularly, when the cooling process S220 is performed simultaneously with the heating process S210, the thermal treatment performed in the heating process S210 may be performed only on the surface of the substrate W. This is because the thermal energy generated in the heating unit 500 is minimized from reaching the lower surface of the substrate W due to the cooling gas supplied to the lower surface of the substrate W by the cooling process S220, so that the thermal treatment may be concentrated on the surface of the substrate W. In addition, damage to the lower portion of the substrate W may be prevented during the heating process S210.

For the substrate on which the cooling process S220 has been completed, when a subsequent cycle exists, the cycle starting with the surface treatment process S100 may be performed again. The surface treatment process S100 may be performed in a state in which the substrate W is seated on the support member 210. Therefore, the process of adjusting the height of the substrate W may be performed between the cooling process S220 and the surface treatment process S100. On the other hand, when a subsequent cycle does not exist, the substrate W may be transferred from the process unit 200 to the load lock chamber 15 and may be carried out from the facility. Alternatively, the substrate W may be transferred to another type of process unit 200, and a different type of substrate treatment may be performed.

As described above, according to the present disclosure, by rapidly cooling the heated substrate W, a temperature increase phenomenon of the entire substrate W by a repetitive process may be prevented, and a temperature increase phenomenon of the treatment space may be prevented. Accordingly, even in the repetitive process that is characteristic of the atomic layer level treatment process (for example: ALD, ALE), the substrate may be treated under the same process condition. That is, process stability and reproducibility may be secured.

Particularly, in the present disclosure, since the substrate W is cooled in the non-contact manner by using the cooling gas while the substrate W is moved upward from the support member 210, the cooling efficiency may be controlled by adjusting the condition of the cooling gas and the height of the substrate W. In addition, since the substrate W is cooled by the cooling gas that is directly in contact with the lower surface of the substrate W, the cooling efficiency realized under the same process condition is higher than cooling efficiency of the conventional method.

In addition, according to the present disclosure, since overheating of the substrate W is prevented, damage to the substrate such as deformation of the substrate, damage to the pattern, damage to the surface, and so on due to overheating of the substrate W may be prevented. In addition, changes in the physical properties of the thin film that that may occur as the temperature of the substrate W exceeds an allowable range may be minimized.

In addition, the process time may be reduced by rapid heating and rapid cooling. Furthermore, since the cooling treatment is capable of being performed regardless of a change in the height of the substrate W, intensive thermal treatment may be performed on the surface of the substrate W by cooling the lower surface of the substrate W while the heating process is performed.

The present exemplary embodiment and the accompanying drawings in this specification only clearly show a part of the technical idea included in the present disclosure, and it will be apparent that all modifications and specific exemplary embodiments that can be easily inferred by those skilled in the art within the scope of the technical spirit contained in the specification and drawings of the present disclosure are included in the scope of the present disclosure.

Therefore, the spirit of the present disclosure should not be limited to the described exemplary embodiments, and all things equal or equivalent to the claims as well as the claims to be described later fall within the scope of the concept of the present disclosure.

What is claimed is:

1. A substrate treatment method comprising:
a heating process in which a surface of a substrate is heated; and
a cooling process in which the substrate is cooled by supplying a cooling gas to a lower surface of the substrate.

2. The substrate treatment method of claim 1, wherein each of the heating process and the cooling process is performed in a state in which the substrate is moved upward from an upper surface of a support member where the substrate is seated.

3. The substrate treatment method of claim 2, wherein the cooling process comprises a process of controlling a cooling condition, and the cooling condition comprises a discharge amount of the cooling gas and a temperature of the cooling gas.

4. The substrate treatment method of claim 3, wherein the cooling condition further comprises a separation distance between the substrate and the upper surface of the support member.

5. The substrate treatment method of claim 4, wherein the cooling process is performed simultaneously with the heating process, or is performed immediately after the heating process.

6. The substrate treatment method of claim 2, wherein the heating process is performed by an upper heat source comprising any one of a microwave generator, a laser generator, and an infrared lamp.

7. The substrate treatment method of claim 6, wherein the heating process comprises a process of controlling a heating condition, and the heating condition comprises a separation distance between the substrate and a heating unit.

8. A substrate treatment apparatus comprising:
a chamber having a treatment space therein;
a support member which is disposed in an internal space of the treatment space and on which a substrate to be treated is seated, the support member being provided with a plurality of gas discharge holes;
a lift pin configured to lift the substrate from the support member;
a cooling unit configured to cool the substrate by discharging a cooling gas through the gas discharge holes;
a heating unit configured to heat the substrate by supplying thermal energy to the treatment space; and
a controller configured to control the lift pin, the cooling unit, and the heating unit.

9. The substrate treatment apparatus of claim 8, wherein the controller is configured to control the lift pin so that a substrate treatment process by the heating unit and the cooling unit is performed in a state in which the substrate is spaced apart from an upper surface of the support member.

10. The substrate treatment apparatus of claim 9, wherein the controller is configured to control the cooling unit, thereby controlling a discharge amount of the cooling gas to the substrate and a temperature of the cooling gas.

11. The substrate treatment apparatus of claim 10, wherein, when the cooling unit cools the substrate, the controller adjusts a separation distance between the substrate and the upper surface of the support member by controlling a lifting height of the lift pin.

12. The substrate treatment apparatus of claim 9, wherein, when the heating unit heats the substrate, the controller adjusts a separation distance between the substrate and the upper surface of the support member by controlling a lifting height of the lift pin.

13. The substrate treatment apparatus of claim 10, wherein the heating unit comprises any one of a microwave generator, a laser generator, and an infrared lamp.

14. A substrate treatment method of etching a surface of a substrate at an atomic layer level, the substrate treatment method comprising:
a surface treatment process in which the surface of the substrate is modified by using plasma; and
a thermal treatment process for generating a desorption reaction on the surface of the substrate that is surface-treated in the surface treatment process,
wherein the surface treatment process and the thermal treatment process constitute one cycle and are repeated one or more times, and
the thermal treatment process comprises:
a heating process in which the surface of the substrate is heated; and
a cooling process in which the substrate is cooled by supplying a cooling gas to a lower surface of the substrate.

15. The substrate treatment method of claim 14, wherein each of the heating process and the cooling process is performed in a state in which the substrate is moved upward from an upper surface of a support member where the substrate is seated.

16. The substrate treatment method of claim 15, wherein the cooling process comprises a process of controlling a cooling condition, and the cooling condition comprises a discharge amount of the cooling gas, a temperature of the cooling gas, and a separation distance between the substrate and the upper surface of the support member.

17. The substrate treatment method of claim 16, wherein, in the cooling process, the substrate is cooled such that a temperature of the substrate is maintained in a set temperature range, and the cooling process is performed after the heating process is performed or is performed simultaneously with the heating process.

18. The substrate treatment method of claim 15, wherein the heating process is performed by an upper heat source comprising any one of a microwave generator, a laser generator, and an infrared lamp, and the heating process comprises a process of adjusting a distance between the substrate and the upper heat source.

19. The substrate treatment method of claim 14, wherein the surface treatment process comprises:
an oxidation process in which a process gas including oxygen is supplied to a treatment space where the substrate exists and then the process gas is converted into plasma, thereby oxidizing the surface of the substrate; and
a modification process in which a ligand of the surface that is oxidized by the oxidation process is exchanged by supplying a precursor to the treatment space.

20. The substrate treatment method of claim 19, wherein the surface treatment process further comprises a purge process purging the treatment space, and the purge process is performed between the oxidation process and the modification process and is performed after the modification process.
